(19) United States
(12) Patent Application Publication
(10) Pub. No.: US 2025/0323208 A1
(43) Pub. Date: Oct. 16, 2025

(54) METHOD FOR FORMING AN ELECTRONIC DEVICE

(71) Applicant: JCET STATS ChipPAC Korea Limited, Incheon (KR)

(72) Inventors: YeoJun YUN, Incheon (KR); SeungHyun LEE, Incheon (KR); HeeSoo LEE, Incheon (KR)

(21) Appl. No.: 19/173,851

(22) Filed: Apr. 9, 2025

(30) Foreign Application Priority Data
Apr. 10, 2024 (CN) 202410426485.4

(51) Int. Cl. H01L 23/00

(52) U.S. Cl. CPC H01L 24/81; H01L 2224/81024; H01L 2224/8122

(57) ABSTRACT

An electronic device and a method for forming the same is provided. The method comprises: providing a first chip comprising first through-silicon vias (TSV) and a second chip comprising second TSVs, wherein first connecting bumps are attached on a lower surface of the first chip, and at least a portion of the first connecting bumps are connected to respective ones of the first TSVs; coating a first flux on the first connecting bumps; contacting the first connecting bumps to an upper surface of the second chip, to form connections between at least a portion of the first connecting bumps and respective ones of the second TSVs; and heating the first connecting bumps and the first flux by irradiating the first connecting bumps and the first flux with microwave, to form connections between the first chip and the second chip.

### TECHNICAL FIELD

The present application generally relates to semiconductor technology, and more particularly, to a method for forming an electronic device.

### BACKGROUND OF THE INVENTION

Through-Silicon Via (TSV) technology stands out as a leading solution for minimizing electrical parasitic components related to wiring, which is crucial for reducing wiring delay time. With its ability to offer the shortest electrical wiring compared to bonding wire or flip chip technology, the TSV technology has recently attracted attention for providing the most effective answer to improving electrical performance. However, the non-uniformity of thermal energy transfer in the conventional Laser-Assisted Bonding (LAB) process may have adverse effects on multi-stack electronic devices employing the TSV technology. Specifically, the non-uniform heat transfer in the conventional LAB process may induce warpage issues, which can adversely affect device performance and subsequent fabrication processes.

Therefore, a need exists for further improvement for forming an electronic device employing the TSV technology.

### SUMMARY OF THE INVENTION

An objective of the present application is to provide a method for forming an electronic device employing TSV technology with less warpage issues.

According to an aspect of the present application, a method for forming an electronic device is provided. The method comprises: providing a first chip comprising first through-silicon vias (TSV) and a second chip comprising second TSVs, wherein first connecting bumps are attached on a lower surface of the first chip, and at least a portion of the first connecting bumps are connected to respective ones of the first TSVs; coating a first flux on the first connecting bumps; contacting the first connecting bumps to an upper surface of the second chip, to form connections between at least a portion of the first connecting bumps and respective ones of the second TSVs; and heating the first connecting bumps and the first flux by irradiating the first connecting bumps and the first flux with microwave, to form connections between the first chip and the second chip.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1E illustrate various steps of a method for forming an electronic device according to a first embodiment of the present application.

FIG. 2 illustrates a microwave radiation step of a method for forming an electronic device according to a second embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

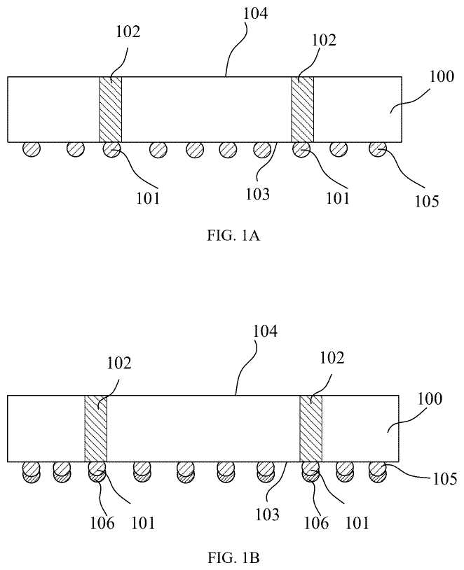

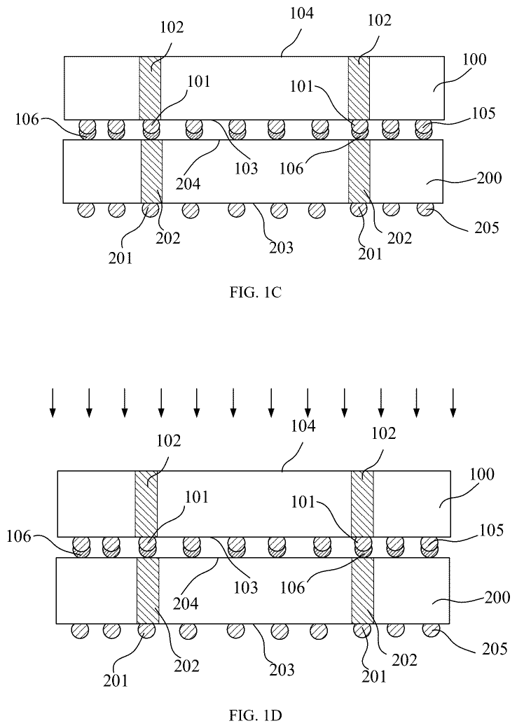

FIGS. 1A to 1E illustrate various steps of a method for forming an electronic device according to a first embodiment of the present application. The following describes the method in greater detail with reference to FIGS. 1A to 1E.

As shown in FIG. 1A, a first chip 100 with two first through-silicon vias (TSVs) 102 is provided. The first chip 100 may be any type of semiconductor chips. For instance, the first chip 100 can be a memory chip like a volatile memory (such as DRAM) or a non-volatile memory (such as ROM), a logic chip like an analog-digital converter or an application-specific IC (ASIC), or other types of semiconductor chips such as a power management IC (PMIC) or an optical sensor. Furthermore, the first chip 100 includes at least a non-polar material. It can be appreciated that, the first chip 100 may include a minor amount of polar materials such as encapsulants or adhesives other than the non-polar material. For example, the first chip 100 may contain more than 99 wt. %, 98 wt. %, 95 wt. % or 90 wt. % of non-polar material(s), and accordingly less than 1wt. %, 2 wt. %, 5 wt. % or 10 wt. %. of polar materials.

The number and shape of the first TSVs 102 shown in FIG. 1A are merely exemplary. In some embodiments, the first chip 100 may include any number of first TSVs 102 and the first TSVs 102 may have any shapes or configurations. In some embodiments, at least some of the first TSVs 102 are vertical vias extending completely from an upper surface 104 to the lower surface 103 of the first chip 100. Alternatively, at least one of the first TSVs 102 may extend only a portion of the first chip 100. For instance, the first chip 100 may has a first substrate, and at least some of the first TSVs 102 may extend entirely through the first substrate of the first chip 100. Furthermore, in some embodiments, the plurality of the first TSVs 102 of the first chip 100 may adopt the same shape or configuration, or different shapes or configurations.

Further referring to FIG. 1A, the first chip 100 has two first connecting bumps 101 attached on its lower surface 103. The two first connecting bumps 101 are electrically connected to the respective first TSVs 102. In some embodiments, each of the first connecting bumps 101 may establish electrical connection with the first TSV 102 through direct contact. In some embodiments, the first connecting bump 101 can be electrically connected to the first TSV 102 without being in direct contact with the first TSV 102. For instance, the first chip 100 may have an additional wiring layer (not shown) formed at its bottom side, which includes a wiring structure connecting the first TSV 102 to the first connecting bump 101 attached on the additional wiring layer. The wiring structure may include wires and/or vertical contacts, for example.

The first connecting bumps 101 may be formed by depositing a solder material onto the lower surface 103 of the first chip 100. In some embodiments, each first connecting bump 101 may include a metal material, a combination of metal materials, or a combination of metal and non-metal materials. To be more specific, the solder materials may be Al, Sn, Ni, Au, Ag, lead (Pb), bismuth (Bi), Cu, or combinations thereof. In some embodiments, the first connecting bumps 101 may include metal powders. For example, the first connecting bumps 101 may be sintered metal powders. In some other embodiments, the first connecting bumps 101 may include metal powders and an adhesive material gluing the metal powders. The adhesive material should be sticky enough to glue the metal powders together before, during and after a subsequent heating process of the first connecting bumps 101. In other words, the adhesive material should not volatilize completely during the heating process of the first connecting bumps 101. In addition, the adhesive material may include a thermal conductive material, which allows for an efficient convection heat transfer within each first connecting bump 101 during the heating process. In some alternative embodiments, the adhesive material may include a polar material, which further facilitates a heating process of the first connecting bumps 101 when they are exposed to microwave radiation subsequently, since the adhesive material may absorb microwave energy and may thus be particularly heated. In addition to the two first connecting bumps 101, as shown in FIG. 1A, another plurality of first connecting bumps 105 are also attached on the lower surface 103 of the first chip 100. The first connecting bumps 105 may not be aligned with the first TSVs 102, but may be aligned with other conductive structures on the lower surface 103 of the first chip 100, e.g., conductive patterns or pads, or aligned with and connected with non-conductive structures. It can be appreciated that the first connecting bumps 105 may be formed using the same material as the first connecting bump 101 and using the same deposition process. In some embodiments, the first connecting bumps 105 that are aligned with or connected to the conductive patterns or pads of the first chip 100 may form conductive structures for electrically interconnecting with the conductive features of other electronic components. In addition, the first connecting bumps 105 that are aligned with non-conductive structures may be used for mechanical supports instead of electrical connections.

Next, as shown in FIG. 1B, a first flux 106 is coated onto respective surfaces of the first connecting bumps 101. The first flux 106 may facilitate a subsequent heating process of the first connecting bumps 101 and then may enable sufficient electrical connection between the first chip 100 and other chips or electronic components through the first connecting bumps 101. The first flux 106 includes a significant amount of a polar material or polar materials, which can be effectively heated when exposed to microwave radiation. Furthermore, in some embodiments, the first flux 106 includes a polar material or polar materials with a degree of polarization higher than that of the first connecting bumps 101. Therefore, when exposed to microwave radiation, the first flux 106 may be heated to a higher temperature compared with the first connecting bumps 101, which enables a sufficient convection heat transfer from the first flux 106 to the first connecting bumps 101. In some embodiments, the first flux 106 may possess a dielectric constant or a dielectric loss factor that is higher than the dielectric constant or a dielectric loss factor of the first connecting bumps 101. Therefore, the first flux 106 would absorb microwave energy more efficiently than the first connecting bumps 101 during microwave irradiation. In some embodiments, the first flux 106 may include one or more materials selected from the following group: nonylphenol ethoxylate, glyceryl monostearate, acid activator, water and mineral salt. In a preferred embodiment, the first flux 106 may include between 40 wt. % and 70 wt. % of nonylphenol ethoxylate, between 10 wt. % and 30 wt. % of glyceryl monostearate, between 3 wt. % and 10 wt. % of acid activator, between 3 wt. % and 10 wt. % of water, and between 4 wt. % and 15 wt. % of mineral salt.

In the embodiment shown in FIG. 1B, the first flux 106 is coated onto respective bottom surfaces of the first connecting bumps 101. In some other embodiments, the first flux 106 may be coated onto the entire surfaces of the first connecting bumps 101 which are exposed from the back surface of the first chip 100, so as to increase contact areas between the first flux 106 and the first connecting bumps 101, therefore enhancing the convection heat transfer from the first flux 106 to the respective first connecting bumps 101. In addition, as shown in FIG. 1B, the first flux 106 is also coated to all of the first connecting bumps 105 to facilitate a subsequent heating process of these connecting bumps. The flux coating process may be conducted by dipping the connecting bumps within a container of flux using a flux dipping apparatus. In some embodiments, excess flux may be applied to each of the first connecting bumps 101 to improve the amount of the polar materials, thereby achieving improved efficiency in microwave energy absorption.

Subsequently, as shown in FIG. 1C, a second chip 200 having two second TSVs 202 is provided. In particular, the first chip 100 is stacked onto an upper surface 204 of the second chip 200, enabling direct contact between the first connecting bump 101 coated with the first flux 106 and the upper surface 204 of the second chip 200, thereby forming a connection between the first connecting bump 101 and the second TSV 202. It should be understood that “forming a connection” refers to either direct connection or indirect connection with the presence of intervening elements. In some embodiments, the first connecting bump 101 coated with the first flux 106 directly contacts the second TSV 202. In other embodiments, the first connecting bump 101 coated with the first flux 106 contacts a conductive feature, such as a pad or a conductive pattern, which is electrically connected with the TSV 202. Therefore, the first flux 106 is between the bottom surfaces of the first connecting bumps 101 and the upper surfaces 204 of the second chip 200. It can be appreciated that the first flux 106 may flow slightly towards the second chip 200 due to surface tension, but a significant portion of the surfaces of the first connecting bumps 101 may still be coated with the first flux 106.

Following this, as shown in FIG. 1D, a microwave source is positioned above the first chip 100, and microwave radiation is emitted from the microwave source to the first chip 100 to heat the first connecting bumps 101 and the first flux 106. Since the first chip 100 typically includes non-polar material(s), it may not absorb microwave energy, or may absorb only minimal microwave energy. Consequently, the microwave can penetrate through the first chip 100 and the first connecting bumps 101 and reach the first flux 106. In some other embodiments, the microwave source is placed at one or more lateral sides of the first chip 100. The microwave radiation may be applied from the microwave source to the first connecting bump 101 and the first flux 106 from their lateral side(s). Therefore, the microwave may interact with the first connecting bumps 101 and the first flux 106 more directly without first going through the first chip 100, which may increase energy absorption efficiency. It can also be appreciated that the position where the microwave source is placed may vary according to actual layouts of the electronic device. For example, one or more microwave sources may be inclined for 30 degrees, 45 degrees, 60 degrees or any other suitable degrees with respect to the upper surface 204 of the second chip 200.

Still referring to FIG. 1D, as the first connecting bumps 101 and the first flux 106 coated thereon are subjected to the microwave radiation, dipoles within the polar molecules of the first flux 106 are sensitive to an electrical field of the microwave and may rotate to align themselves with a direction of the electrical field. The electrical field of the microwave may periodically change, which may prompt the dipoles to rotate frequently. As a result, the dipoles may collide with each other when they attempt to follow the electrical field, which generates heat energy and results in a high temperature rise of the first flux 106, e.g., to a temperature higher than a melting temperature of the first connecting bumps 101. In addition, the first connecting bumps 101, especially the first connecting bumps 101 which include metal powders, may also absorb microwave energy to generate heat, resulting in a moderate temperature rise of the first connecting bumps 101. With the temperature rise of the first flux 106, a part of the heated first flux 106 may volatilize first, and the heat generated in the first flux 106 may be convectively transferred to the first connecting bumps 101, which brings about a further temperature rise of the first connecting bumps 101. Then the temperature of the first connecting bumps 101 may rise to a temperature higher than the melting temperature of the first connecting bumps 101, which induces the first connecting bumps 101 to melt and be reshaped in a reflowing process of the first connecting bumps 101. Finally, as shown in FIG. 1E, the first flux 106 may volatilize completely, allowing the reflowed first connecting bumps 101 to form electronical connection between each pair of the first TSV 102 and the second TSV 202. In some other embodiments, only a part of the first flux 106 may volatilize, and optionally the remaining first flux 106 may be removed from the first connecting bumps 101. In some alternative embodiments, in the following process the remaining first flux 106 and each first connecting bump 101 may melt together to form electronical connection between each pair of the first TSV 102 and the second TSV 202.

During the microwave radiation process, the first flux 106 may be heated to reach a high temperature to provide enough heat to the first connecting bumps 101 through convection, while at the same time, the first flux 106 should not be overheated to avoid complete volatilization before sufficient reflowing of the first connecting bumps 101. In other words, the temperature of the first flux 106 should be controlled within an appropriate range and last for at least a predetermined period. In some embodiments, the appropriate range may be between 120° C. and 350° C. when rosin is used, especially for tin solder bumps which may be melted above 230° C. In some other embodiments, resin flux or other suitable polar flux materials may be used, and the appropriate range may range from the melting temperature of the solder material to a temperature equal to or slightly greater than the vaporization temperature of the first flux 106, e.g., from 10° C. higher than the melting temperature of the solder material to 10° C. higher than the vaporization temperature of the first flux 106, or to 10° C. lower than the vaporization temperature of the first flux 106, for example. In some embodiments, during the microwave radiation process, the first flux 106 is heated to a first temperature while the first connecting bump 101 is heated to a second temperature lower than the first temperature.

In some embodiments, the microwave radiation may be applied intermittently to control the temperature of the heated first flux 106, e.g., the microwave radiation may be applied for a certain period such as 10 seconds to 2 minutes and then be suspended for another certain period such as 5 seconds to 30 seconds, and such cycle may be repeated for several times, depending on the reflowing of the first connecting bump 101. It can be appreciated that the certain period may be several seconds to several minutes, depending on the actual needs of the heating process, such as the specific composition of the first flux 106 and/or the first connecting bumps 101, the number and size of the first connecting bumps 101, and/or the power of the microwave radiation. In some other embodiments, a temperature sensor, e.g., an infrared temperature sensor or an infrared image sensor, may be used to monitor the temperature of the first flux 106 or the first connecting bumps 101, and may then provide real-time temperature measurement(s) to a controller for the microwave source to adjust the power and/or duration of the microwave radiation, for example. In some preferred embodiments, the second chip 200 as well as the first chip 100 mounted thereon may be placed in atmosphere with a high ambient temperature to avoid that during the heating process too much heat is transferred from the first flux 106 and/or the connecting bumps 101 to the first chip 100 and/or the second chip 200 due to a significant temperature difference between them and the first connecting bump 101 or the first flux 106. For example, the ambient temperature may be 10° C. to 150° C., or preferably 10° C. to 50° C., or more preferably 10°° C. to 30° C., lower than the melting temperature of the first connecting bumps 101.

Furthermore, in this embodiment, the microwave radiation is applied at a variable frequency during the microwave radiation step. By sweeping a range of frequencies rapidly, the microwave radiation process may increase the uniformity of microwave energy in comparison with a fixed-frequency microwave radiation. For example, the changing microwave radiation may be applied at a frequency ranging between 1 GHz and 40 GHZ, with a preferred range between 1 GHz and 10 GHz. In some embodiments, the frequency of the microwave varies continuously during the irradiation to the first connecting bumps 101 and the first flux 106. In other embodiments, the frequency of the microwave varies between a group of discrete values during the irradiation to the first connecting bumps 101 and the first flux 106. These discrete values may be selected from specific frequencies that match the resonance frequencies of certain materials in the first connecting bumps 101 or the first flux 106, aiming to improve their energy absorbing efficiency.

The microwave source may be set at a power ranging between 100 W and 2000 W. In other embodiments, the microwave radiation may be applied at a frequency higher than 10 GHz or with a microwave source power higher than 1000 W, which allows for a more rapid temperature rise of the first connecting bumps 101 and the first flux 106. In addition, the microwave radiation may last for a minimum duration, such as 1 minute to allow for sufficient reflowing of the first connecting bumps 101 and complete volatilization of the first flux 106, thereby forming effective electrical connection between the first TSV 102 and the second TSV 202 and avoiding further cleaning of the residual flux material after the reflowing process. It can also be appreciated that the frequency, power and duration of the microwave radiation may be determined according to actual needs of the reflowing process of the first connecting bumps 101. At the same time, since the molecules in non-polar materials are not sensitive to the electrical field of the microwave radiation, the first chip 100 and second chip 200 may not be heated or may barely be heated by the microwave radiation when they are exposed to the microwave field together with the first connecting bumps 101 and the first flux 106. In addition, interconnect wires or metal layers within the first chip 100 and the second chip 200 may reflect the microwave and may barely generate heat energy. In this way, the first connecting bumps 101 and the first flux 106 are selectively heated by the microwave radiation. This heating mechanism may offer multiple advantages to the conventional reflowing process of the first connecting bumps 101 utilizing heating. Firstly, different form the conventional heating process applied to the entire electronic device, the selective heating of the first connecting bumps 101 and the first flux 106 by microwave radiation may reduce the warpage issues of the first chip 100 since the first chip 100 is barely heated by the microwave radiation. Secondly, the microwave can penetrate through the first flux 106 and the first connecting bumps 101 to supply energy, and thus the heat can be generated throughout the first connecting bumps 101 in a volumetric manner, which allows for a more uniform heat distribution from the surface to the interior of each first connecting bump 101. Thirdly, the microwave induces molecular rotation without destroying molecular bonds due to low energy per photon, which may have little influence on the internal structure of the electronic device. Fourthly, the microwave heating can be started and/or ended quickly, which may reduce the heating duration and thus power consumption.

As previously mentioned, all of the first connecting bumps 105 attached on the lower surface 103 may consist of the same or similar materials with the first connecting bumps 101. Furthermore, the microwave irradiation process described above may also melt the first connecting bumps 105 together with their respective first flux 106, thereby forming additional connection between the first chip 100 and the second chip 200. Furthermore, the method described above may also include additional steps. For instance, the first chip 100 may be compressed towards the second chip 200 during or after the heating of the first connecting bump 101 and the first flux 106, thus establishing a more stable connection between the two chips. As another example, the method may involve aligning the first chip 100 with the second chip 200 in a vertical direction before bringing the first connecting bumps 101 into contact with the upper surface 204 of the second chip 200. In some embodiments, the first TSV 102 and the second TSV 202 are aligned with each other in a vertical direction during this step. Furthermore, encapsulants, shielding materials may be formed outside of the entire electronic device.

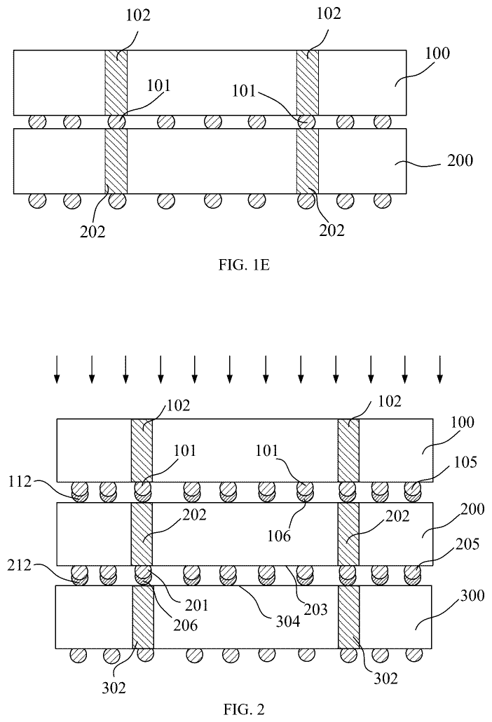

FIG. 2 illustrates a microwave radiation step of a method for forming an electronic device according to a second embodiment of the present application. The step illustrated in FIG. 2 may be implemented after the steps illustrated in FIGS. 1A to 1C have been performed, instead of the steps illustrated in FIGS. 1D and 1E, as an alternative embodiment to the embodiment shown in FIGS. 1A to 1E.

In the embodiment shown in FIG. 2, similar to the first chip 100, the second chip 200 has two second connecting bumps 201 attached on a lower surface 203 of the second chip 200, and each second connecting bump 201 is electrically connected to a corresponding second TSV 202. In addition to the two second connecting bumps 201, another plurality of second connecting bumps 205 are also attached on the lower surface of the second chip 200. The second connecting bumps 205 may not be aligned with the second TSVs 202, but may be aligned with other conductive structures e.g., conductive patterns or pads, on the lower surface 203 of the second chip 200, or aligned with and connected with non-conductive structures. Furthermore, a second flux 206 is coated onto respective surfaces of the second connecting bumps 201, 205. The forming process, materials used, connections with other parts of the second connecting bumps 201, 205 and the second flux 206 are similar to those of the first connecting bumps 101, 105 and the first flux 106 as described with reference to the embodiment shown in FIGS. 1A to 1E, and will not be detailed again.

The stacked first chip 100 and second chip 200 are further stacked onto an upper surface 304 of a third chip 300, which similarly has two third TSVs 302, thereby enabling contact between the second connecting bumps 201 coated with the second flux 206 and the upper surface 304 of the third chip 300. Therefore, the second flux 206 is between the bottom surfaces of the second connecting bumps 201 and the upper surfaces 304 of the third chip 300, respectively. It can be appreciated that the second flux 206 may also flow slightly towards the third chip 300 due to surface tension, but a significant portion of the respective surfaces of the second connecting bumps 201 may still be coated with the second flux 206.

As shown in FIG. 2, a microwave source is positioned above the first chip 100, and microwave radiation is emitted from the microwave source to the first chip 100 to heat the first connecting bumps 101, 105, the first flux 106, the second connecting bumps 201, 205 and the second flux 206 simultaneously. The parameters related to the microwave irradiation process employed in the step shown in FIG. 2 may be similar to those described in the step shown in FIG. 1D, and will not be detailed again. In some embodiments, the first connecting bumps 101, 105 and the first flux 106 may not be heated simultaneously with the second connecting bumps 201, 205 and the second flux 206. Specifically, the steps illustrated in FIGS. 1A to 1E may be performed first. Subsequently, the stacked first chip 100 and second chip 200 shown in FIG. 1E may be disposed onto the upper surface 304 of the third chip 300 and a microwave radiation process may be performed to heat the second connecting bumps 201, 205 and the second flux 206. It can be appreciated that, although FIG. 2 depicts only three chips, the number of chips stacked together may not be limited to three, and may be more than three in some examples.

While not depicted in the figures, in some embodiments, the first connecting bumps 101 may initially be integrated with the second chip 200 rather than the first chip 100. Specifically, the first connecting bumps 101 are attached on the upper surface 204 of the second chip 200 and electrically connected to the respective second TSVs 202. In such scenario, the flux coating process, as described with reference to FIG. 1B, is performed on both of the first connecting bumps 101 and the second connecting bumps 201 attached on the second chip 200. Subsequently, the first connecting bumps 101 are attached to the lower surface 103 of the first chip 100 to establish a connection between each pair of the first connecting bump 101 and the first TSV 102. Meanwhile, the second connecting bumps 201 are attached to the upper surface 304 of the third chip 300 to form connections between the second connecting bumps 201 and the third TSVs 302. Following this, a microwave radiation process may be employed to heat the first connecting bumps 101, the second connecting bumps 201, and the coated flux, thereby forming electrical connections between the first TSVs 102, the second TSVs 202 and the third TSVs 302.

In some embodiments, the first chip 100, the second chip 200, and the third chip 300 may be the same type of semiconductor chip. For instance, they may each be a memory semiconductor chip. The memory semiconductor chip may be, for example, a volatile memory semiconductor chip, such as DRAM or static random access memory (SRAM), or a non-volatile memory semiconductor chip, such as phase-change random access memory (PRAM), magnetoresistive random access memory (MRAM), ferroelectric random access memory (FeRAM), or resistive random access memory (RRAM).

In some embodiments, the first chip 100, the second chip 200, and the third chip 300 may include different types of semiconductor chips. For instance, one or more of the first chip 100, the second chip 200, and the third chip 300 may be logic chips, while others may be memory chips. For example, the logic chip includes a central processing unit (CPU) chip, a graphics processing unit (GPU) chip, and/or an application processor (AP) chip.

In some embodiments, after the step shown in FIG. 1E or FIG. 2, a substrate may be further provided. The stacked chips may be formed on the substrate and an encapsulant layer may also be formed on the substrate to encapsulate the stacked chips, therefore forming an electronic package. In some other embodiments, the method for forming the electronic device may not include the process of forming an encapsulant layer.

While the exemplary method for forming an electronic device of the present application is described in conjunction with corresponding figures, it will be understood by those skilled in the art that modifications and adaptations to the method for forming an electronic device may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming an electronic device, comprising:
providing a first chip comprising first through-silicon vias (TSV) and a second chip comprising second TSVs, wherein first connecting bumps are attached on a lower surface of the first chip, and at least a portion of the first connecting bumps are connected to respective ones of the first TSVs;
coating a first flux on the first connecting bumps;
contacting the first connecting bumps to an upper surface of the second chip, to form connections between at least a portion of the first connecting bumps and respective ones of the second TSVs; and
heating the first connecting bumps and the first flux by irradiating the first connecting bumps and the first flux with microwave, to form connections between the first chip and the second chip.

2. The method of claim 1, wherein the first flux is heated to a first temperature while the first connecting bumps are heated to a second temperature lower than the first temperature.

3. The method of claim 1, wherein the first flux comprises a polar material having a degree of polarization higher than a degree of polarization of the first connecting bumps.

4. The method of claim 1, wherein a dielectric constant or a dielectric loss factor of the first flux is higher than a dielectric constant or a dielectric loss factor of the first connecting bumps.

5. The method of claim 1, wherein the first flux comprises one or more materials selected from the following group: nonylphenol ethoxylate, glyceryl monostearate, acid activator, water and mineral salt.

6. The method of claim 5, wherein the first flux comprises between 40 wt. % and 70 wt. % of nonylphenol ethoxylate, between 10 wt. % and 30 wt. % of glyceryl monostearate, between 3 wt. % and 10 wt. % of acid activator, between 3 wt. % and 10 wt. % of water, and between 4 wt. % and 15 wt. % of mineral salt.

7. The method of claim 1, wherein the first connecting bumps comprise metal powders and an adhesive material gluing the metal powders.

8. The method of claim 7, wherein the adhesive material comprises a polar material.

9. The method of claim 7, wherein the adhesive material comprises a thermal conductive material.

10. The method of claim 1, wherein a frequency of the microwave ranges from about 1 GHz to about 40 GHz.

11. The method of claim 1, wherein a frequency of the microwave varies during irradiation of the first connecting bumps and the first flux.

12. The method of claim 11, wherein the frequency of the microwave varies continuously during irradiation of the first connecting bumps and the first flux.

13. The method of claim 11, wherein the frequency of the microwave varies between a group of discrete values during irradiation of the first connecting bumps and the first flux.

14. The method of claim 1, further comprising:
compressing the first chip towards the second chip during or after heating the first connecting bumps and the first flux.

15. The method of claim 1, wherein the second chip has second connecting bumps attached on its lower surface, and at least a portion of the second connecting bumps are connected to respective ones of the second TSVs, and the method further comprises:
providing a third chip comprising third TSVs;
coating a second flux on the second connecting bumps;
contacting the second connecting bumps to an upper surface of the third chip to form connections between at least a portion of the second connecting bumps and respective ones of the third TSVs; and
heating the second connecting bumps and the second flux by irradiating the second connecting bumps and the second flux with microwave, to form connections between the second chip and the third chip.

16. The method of claim 15, wherein the second connecting bumps and the second flux are heated simultaneously with the first connecting bumps and the first flux.

17. An electronic device which is formed using the method of claim 1.

18. An electronic device which is formed using the method of claim 15.
